(19) United States
(12) Patent Application Publication
(10) Pub. No.: US 2025/0292807 A1
(43) Pub. Date: Sep. 18, 2025

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventor: Hirokazu SHIOMICHI, Yokkaichi Mie (JP)

(21) Appl. No.: 19/062,834

(22) Filed: Feb. 25, 2025

(30) Foreign Application Priority Data
Mar. 18, 2024 (JP) 2024-041970

(51) Int. Cl. G11C 5/06; H01L 23/528; H01L 23/532

(52) U.S. Cl. CPC G11C 5/063; H01L 23/5283; H01L 23/53295

(57) ABSTRACT

A semiconductor memory device includes a stacked body including first conductive layers and first insulating layers alternately stacked on top of one another. The stacked body further includes a staircase portion with terrace surfaces respectively formed with the plurality of first conductive layers and step surfaces connecting the terrace surfaces, the staircase portion extending in a first direction intersecting the stacking direction. Each of the plurality of first conductive layers includes a first layer thickness and a second layer thickness, the first layer thickness corresponding to a portion of the first conductive layer forming the corresponding terrace surface and the second layer thickness corresponding to another portion of the first conductive layer, the first layer thickness is greater than the second layer thickness. Each of the first insulating layers has a tapered portion extending toward a corresponding one of the terrace surfaces.

### CROSS-REFERENCE TO RELATED APPLICATION(S)

This application is based upon and claims the benefit of priority from Japanese Patent Application No. 2024-041970, filed Mar. 18, 2024, the entire contents of which are incorporated herein by reference.

### FIELD

Embodiments described herein relate generally to a semiconductor memory device and a method for manufacturing the semiconductor memory device.

### BACKGROUND

Examples of a three-dimensional nonvolatile memory include one having a stacked body in which a plurality of conductive layers and a plurality of insulating layers are alternately stacked. The stacked body has, at an end, a staircase portion. The staircase portion is formed by processing the stacked body into a staircase shape and serves to lead out the individual conductive layers to upper layer wiring.

As the stacked body becomes thinner and the number of stacked layers increases, processing the staircase portion becomes more difficult. Improper formation of the staircase portion sometimes reduces the electrical characteristics of a semiconductor memory device.

### DESCRIPTION OF THE DRAWINGS

FIGS. 1A and 1B are diagrams illustrating an example of a schematic configuration of a semiconductor memory device according to a first embodiment.

FIGS. 2A and 2B are diagrams illustrating an example of a detailed configuration of the semiconductor memory device according to the first embodiment.

FIGS. 3A and 3B are diagrams sequentially illustrating some procedures of a method for manufacturing the semiconductor memory device according to the first embodiment.

FIGS. 4A and 4B are diagrams sequentially illustrating some procedures of a method for manufacturing the semiconductor memory device according to the first embodiment.

FIGS. 5A and 5B are diagrams sequentially illustrating some procedures of a method for manufacturing the semiconductor memory device according to the first embodiment.

FIGS. 6A and 6B are diagrams sequentially illustrating some procedures of a method for manufacturing the semiconductor memory device according to the first embodiment.

FIGS. 7A to 7C are diagrams illustrating some procedures of a method for manufacturing a semiconductor memory device according to a comparative example.

FIG. 8 is a diagram illustrating an example of a detailed configuration of a semiconductor memory device according to a second embodiment.

FIGS. 9A and 9B are diagrams sequentially illustrating some procedures of a method for manufacturing the semiconductor memory device according to the second embodiment.

### DETAILED DESCRIPTION

Embodiments provide a semiconductor memory device in which improper formation of a staircase portion can be reduced and a method for manufacturing such a semiconductor memory device.

In general, according to one embodiment, a semiconductor memory device includes a stacked body including a plurality of first conductive layers and a plurality of first insulating layers alternately stacked on top of one another. The stacked body further includes a staircase portion, the staircase portion having a plurality of terrace surfaces respectively formed with the plurality of first conductive layers and a plurality of step surfaces connecting the plurality of terrace surfaces in a stacking direction of the stacked body, the staircase portion extending in a first direction intersecting the stacking direction. Each of the plurality of first conductive layers includes a first layer thickness and a second layer thickness, the first layer thickness corresponding to a portion of the first conductive layer forming the corresponding terrace surface and the second layer thickness corresponding to another portion of the first conductive layer, the first layer thickness is greater than the second layer thickness. Each of the plurality of first insulating layers has a tapered portion extending toward a corresponding one of the terrace surfaces. A width in the first direction of a lower surface of the tapered portion is greater than a layer thickness of each of the first insulating layers.

Hereinafter, embodiments will be described in detail with reference to the drawings. It is noted that the present disclosure is not limited to the embodiments described below. The elements in the following embodiments include those that can be easily assumed by those skilled in the art or those that are substantially the same.

### First Embodiment

### Configuration Example of Semiconductor Memory Device

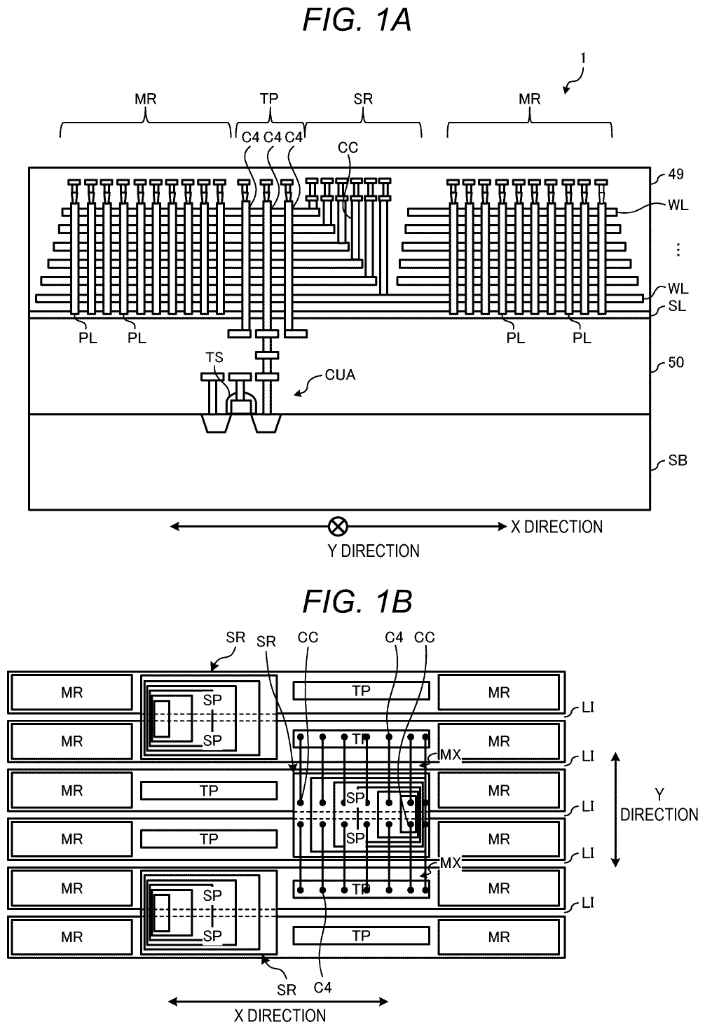

FIGS. 1A and 1B are diagrams illustrating an example of a schematic configuration of a semiconductor memory device 1 according to the first embodiment. FIG. 1A is a cross-sectional view of the semiconductor memory device 1 along an X direction, and FIG. 1B is a schematic plan view illustrating a layout of the semiconductor memory device 1. Meanwhile, in FIG. 1A, hatching is omitted in consideration of the visibility of the drawing. Further, in FIG. 1A, some of select gate lines and upper layer wiring are omitted.

In the present specification, both the X direction and the Y direction are directions along the orientation of planes of word lines WL described later, and the X direction and the Y direction are orthogonal to each other. Further, an electrical drawing direction of the word line WL described later is sometimes referred to as a first direction. The first direction is a direction along the X direction. In addition, a direction intersecting the first direction is sometimes referred to as a second direction. The second direction is a direction along the Y direction. However, the first direction and the second direction are not necessarily orthogonal to each other because there may be a manufacturing error in the semiconductor memory device 1.

As illustrated in FIG. 1A, the semiconductor memory device 1 includes, on a substrate SB, a peripheral circuit CUA, memory regions MR, a through contact region TP, and a staircase region SR.

The substrate SB is, for example, a semiconductor substrate such as a silicon substrate. The peripheral circuit CUA including a transistor TS and wiring is disposed on the substrate SB. The peripheral circuit CUA contributes to the operation of memory cells described later.

The peripheral circuit CUA is covered with an insulating layer 50. A source line SL is disposed on the insulating layer 50. The plurality of word lines WL is stacked on the source line SL. The plurality of word lines WL is covered with an insulating layer 49. The insulating layer 49 also extends around the plurality of word lines WL.

In the plurality of word lines WL, a plurality of plate-shaped contacts LI is disposed. The plurality of plate-shaped contacts LI penetrates the word lines WL in a stacking direction and extends in a direction along the X direction. Thereby, the plurality of word lines WL is divided in the Y direction by the plurality of plate-shaped contacts LI.

The plurality of memory regions MR, the staircase region SR, and the through contact region TP are arranged side by side in the X direction between the plurality of plate-shaped contacts LI. The plurality of memory regions MR is disposed to be separated from each other in the X direction with the staircase region SR and the through contact region TP interposed therebetween.

A plurality of pillars PL penetrating the word lines WL in the stacking direction is disposed in the memory region MR. A plurality of memory cells is formed at an intersection of the pillar PL and the word line WL. Thereby, the semiconductor memory device 1 is configured as, for example, a three-dimensional nonvolatile memory including the memory cells arranged three-dimensionally in the memory region MR.

The staircase region SR includes a plurality of staircase portions SP in which the plurality of word lines WL is dug down in the stacking direction in a mortar shape. In one staircase region SR, for example, two staircase portions SP disposed in the Y direction via one plate-shaped contact LI are provided. The staircase portion SP forms one side of the mortar shape that descends stepwise from both sides in the X direction and one side in the Y direction toward a bottom surface. However, the other side in the Y direction of the staircase portion SP is open toward a side surface of the plate-shaped contact LI.

Each step of the staircase portion SP is configured with the word line WL of each level. The word line WL of each level is electrically conducted on both sides thereof in the X direction with the staircase region SR interposed therebetween via a staircase part on one side of the staircase portion SP in the Y direction. A contact CC for connecting the word line WL of each level to upper layer wiring MX is disposed on a terrace surface of each step of the staircase portion SP.

This allows the word lines WL stacked in multiple layers to be led out individually. From the contacts CC, a write voltage, a read voltage, and so on are applied to the memory cells in the memory regions MR on both sides in the X direction via the word line WL at the same height position as that of the memory cells.

The through contact region TP is provided on one side in the X direction of the staircase region SR. A through contact C4 penetrating the plurality of word lines WL is disposed in the through contact region TP. The through contact C4 connects the peripheral circuit CUA disposed on the substrate SB at a lower place to the upper layer wiring MX connected to the contact CC of the staircase portion SP. Various voltages applied from the contact CC to the memory cells are controlled by the peripheral circuit CUA via the through contact C4, the upper layer wiring MX, and the like.

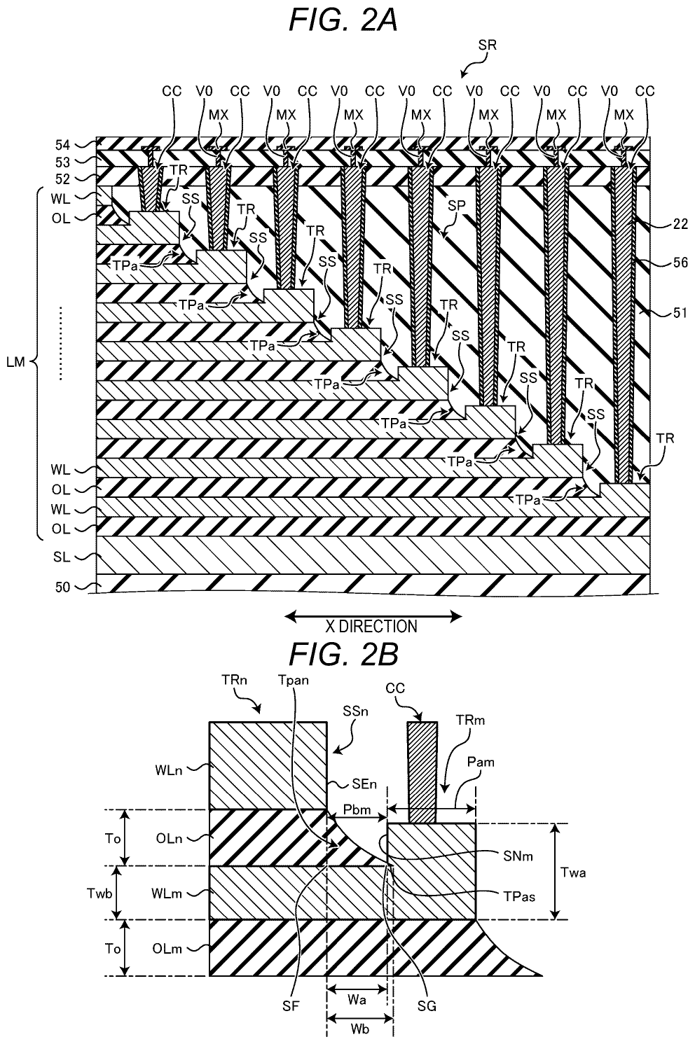

FIGS. 2A and 2B are diagrams illustrating an example of a detailed configuration of the semiconductor memory device 1 according to the first embodiment. FIG. 2A is a cross-sectional view of the staircase region SR along the X direction. FIG. 2B is a partially enlarged view illustrating a cross-section of the staircase portion SP disposed in the staircase region SR. Meanwhile, in FIG. 2A, the structure below the insulating layer 50, such as the substrates SB and the peripheral circuit CUA, is omitted.

As illustrated in FIG. 2A, in the staircase region SR, the source line SL is disposed on the insulating layer 50, and a stacked body LM is disposed on the source line SL. The stacked body LM has a structure in which the plurality of word lines WL and a plurality of insulating layers OL are alternately stacked one by one. Each of the plurality of word lines WL is a tungsten layer or a molybdenum layer, for example. Each of the word lines WL is an example of a first conductive layer. Each of the plurality of insulating layers OL is a silicon oxide layer, for example.

The staircase portion SP extending in the X direction is disposed in the stacked body LM. In the staircase portion SP, the plurality of word lines WL and the plurality of insulating layers OL are processed into a staircase shape. The entirety of the staircase region SR including the staircase portion SP is covered with an insulating layer 51 that is a silicon oxide layer, for example. Insulating layers 52 to 54 are formed on the upper surface of the insulating layer 51. The insulating layers 52 to 54 and the insulating layer 51 constitute a part of the insulating layer 49 of FIG. 1.

Each step of the staircase portion SP includes at least one set of the word line WL and the insulating layer OL. In each step, the uppermost layer is the word line WL and the lowermost layer is the insulating layer OL. In the example of FIG. 2A, each step of the staircase portion SP includes one set of the word line WL and the insulating layer OL.

The upper surface of the word line WL in each step of the staircase portion SP is referred to as a terrace surface TR. An end face in the X direction of the word line WL and the insulating layer OL in each step of the staircase portion SP is referred to as a step surface SS. That is, the staircase portion SP includes the plurality of terrace surfaces TR and the plurality of step surfaces SS.

Each of the plurality of step surfaces SS connects the plurality of terrace surfaces TR in the stacking direction. To be specific, each of the plurality of step surfaces SS is connected to the terrace surface TR of the upper step thereabove, and is connected to the terrace surface TR of the lower step therebelow. The end face of the insulating layer OL, which is the lower layer, forming the step surface SS has a tapered portion TPa extending toward the direction of the terrace surface TR.

The layer thickness of a part forming the terrace surface TR of the word line WL is greater than the layer thickness of the rest part of the corresponding word line WL.

It is noted that, in the present specification, the direction in which the terrace surface TR of each step of the staircase portion SP faces is defined as the upward direction.

Each contact CC penetrates the insulating layers 51 and 52 to reach the word line WL of the corresponding step of the staircase portion SP. The contact CC includes an insulating layer 56 covering a side wall of the contact CC and a conductive layer 22 filled inside the insulating layer 56. A lower end of the conductive layer 22 is connected to the terrace surface TR of the corresponding word line WL. An upper end of the conductive layer 22 is connected, via a plug VO extending in the insulating layer 53, to the upper layer wiring MX disposed in the insulating layer 54.

As described above, the semiconductor memory device 1 is provided with the peripheral circuit CUA (see FIG. 1A) and the upper layer wiring MX is electrically connected to the peripheral circuit CUA. The peripheral circuit CUA includes the plurality of transistors TS and contributes to the electric operation of the memory cells. Voltage is applied to the memory cells via the peripheral circuit CUA, the through contact C4, the upper layer wiring MX, the contact CC, and the word line WL to thereby read and write data from and to the memory cells.

Referring to FIG. 2B, the specific positional relationship of the terrace surface TR, the step surface SS, and the tapered portion TPa is described.

FIG. 2B illustrates, for example, a state in which an insulating layer OLm, a word line WLm, an insulating layer OLn, and a word line WIn are stacked one by one from a lower place in the stated order. A layer thickness To of each of the insulating layers OLm and OLn is defined based on a distance at which the word lines WL stacked vertically do not cause a problem in the drive of the device due to electrical influence on each other. Stated differently, as long as the distance between the word lines WL is equal to or greater than the layer thickness To, the word lines WL cause no problems in the drive of the device due to electrical influence on each other.

A terrace surface TRm is formed on the word line WLm, and a terrace surface TRn is formed on the word line WLn. Further, a step surface SSn is connected to the terrace surface TRn thereabove, and is connected to the terrace surface TRm therebelow. The insulating layer OLn, which is the lower layer, forming the step surface SSn has a tapered portion TPan extending toward the terrace surface TRm.

The terrace surface TRm is a part of the upper surface of the word line WLm, and more specifically, is a part projecting in the X direction from a position SF that vertically overlaps an end SEn in the X direction of the word line WIn processed into a staircase shape. The terrace surface TRm includes a first portion Pam where the word line WLm is formed to be thick and a second portion Pbm where the word line WLm is thinner than the word line WLm at the first portion Pam.

The first portion Pam is a region, of the terrace surface TRm, on the end side in the X direction. A layer thickness Twa of the word line WLm at the first portion Pam is greater than a layer thickness Twb of the word line WLm at the second portion Pbm. The contact CC is connected at the first portion Pam. On the other hand, the second portion Pbm is a region, of the terrace surface TRm, on the side opposite to the end in the X direction of the terrace surface TRm. The second portion Pbm is a region, as viewed from above, extending from a position SG at which an end face SNm on the step surface SSn side of the first portion Pam overlaps to a position SF. Accordingly, a width Wa in the X direction of the second portion Pbm corresponds to a distance between the position SF and the end face SNm of the word line WLm.

The tapered portion TPan extends along the second portion Pbm and an end TPas of the tapered portion TPan on the terrace surface TRm side reaches the first portion Pam. That is, the first portion Pam covers the end TPas of the tapered portion TPan on the terrace surface TRm side. As a result, the second portion Pbm is covered with the tapered portion TPan. In such a case, a width Wb in the X direction of the lower surface of the tapered portion TPan is slightly greater than the width Wa in the X direction of the second portion Pbm.

Further, the width Wb in the X direction of the lower surface of the tapered portion TPan is formed to be equal to or greater than the layer thickness To of the insulating layer OLn. That is, the distance between the end SEn of the word line WLn and the end face SNm of the word line WLm is kept to be a distance corresponding to be the layer thickness To or greater. As a result, the word line WIn and the word line WLm are sufficiently spaced from each other in the X direction, which can prevent a problem in the drive of the device due to electrical influence between the word line WLn and the word line WLm.

### Method for Manufacturing Semiconductor Memory Device

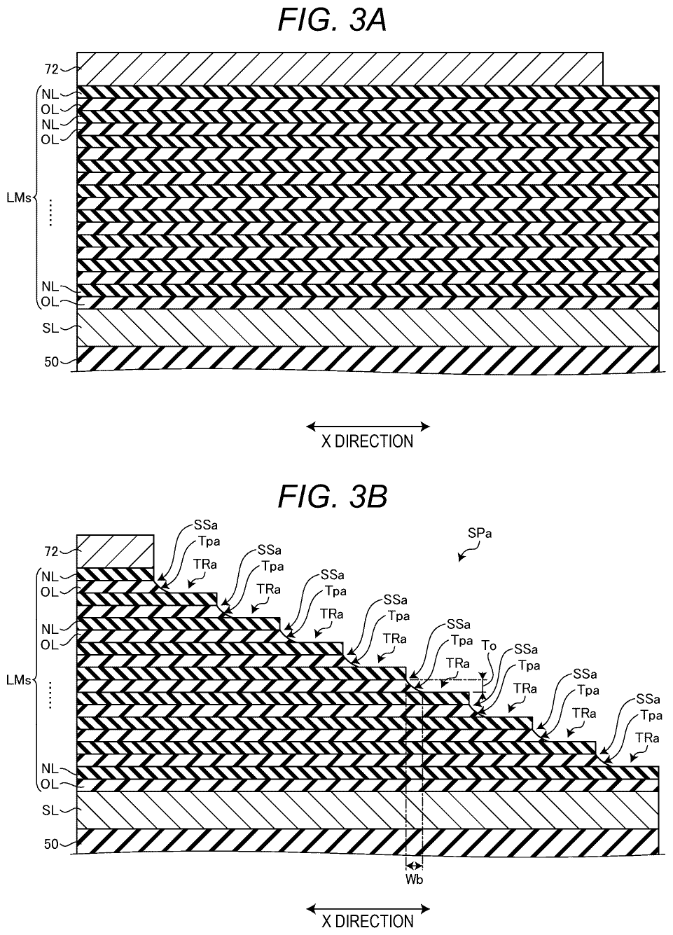

Next, a method for manufacturing the semiconductor memory device 1 according to the first embodiment will be described with reference to FIGS. 3A to 7C. FIGS. 3A to 7C are diagrams sequentially illustrating some procedures of the method for manufacturing the semiconductor memory device 1 according to the first embodiment. It is assumed that, prior to the processing illustrated in FIGS. 3A to 7C, the peripheral circuit CUA is already formed on the substrate SB and the insulating layer 50 covering the peripheral circuit CUA is already formed.

FIGS. 3A to 6B illustrate how the staircase portion SP is formed in a region where the staircase region SR is to be formed later. FIGS. 3A to 6B are cross-sectional views along the X direction of the region where the staircase region SR is to be formed later.

As illustrated in FIG. 3A, the source line SL is formed on the insulating layer 50. On the source line SL, a stacked body LMs in which a plurality of insulating layers NL and the plurality of insulating layers OL are alternately stacked one by one is formed. The lowermost layer of the stacked body LMs is the insulating layer OL and the uppermost layer thereof is the insulating layer NL.

Each of the plurality of insulating layers NL is, for example, a silicon nitride layer. The plurality of insulating layers NL each functions as a sacrificial layer that is to be replaced with the word line WL later. Each of the insulating layers NL is an example of a first insulating layer. Each of the plurality of insulating layers OL is, for example, a silicon oxide layer. Each of the insulating layers OL is an example of a second insulating layer.

On the stacked body LMs, a mask pattern 72 covering a part of the stacked body LMs is formed. The mask pattern 72 is, for example, a carbon-containing layer. The insulating layer NL and the insulating layer OL at an exposed part are removed one by one by etching using the mask pattern 72. Then, by processing using oxygen plasma for example, an end of the mask pattern 72 is retracted to newly expose the upper surface of the stacked body LMs, and then the insulating layer NL and the insulating layer OL are removed one by one by etching.

Slimming the mask pattern 72 in this manner and etching the insulating layer NL and the insulating layer OL of the stacked body LMs are repeated a plurality of times. As a result, a staircase portion SPa as a first staircase portion is formed as illustrated in FIG. 3B.

The staircase portion SPa extends in the X direction, and has a shape in which the plurality of insulating layers NL and the plurality of insulating layers OL are processed into a staircase shape. The staircase portion SPa includes a plurality of terrace surfaces Tra formed with the plurality of insulating layers NL and a plurality of step surfaces SSa. The plurality of step surfaces SSa connects the plurality of terrace surfaces TRa in the stacking direction of the stacked body LMs.

The terrace surface TRa is the upper surface of the insulating layer NL in each step of the staircase portion SPa. Further, the step surface SSa is the end face in the X direction of the insulating layer NL and the insulating layer OL in each step of the staircase portion SPa. The step surface SSa on the upper layer side is the insulating layer NL and the step surface SSa on the lower layer side is the insulating layer OL. The step surface SSa is connected to the terrace surface TRa on the upper side of the insulating layer NL and to the terrace surface TRa on the lower side of the insulating layer OL. The terrace surface TRa is an example of a first terrace surface. The step surface SSa is an example of a first step surface.

When the staircase portion SPa is formed, processing is performed such that the insulating layer OL that is the lower layer of the step surface SSa has a tapered portion TPa extending toward the terrace surface TRa connected to the step surface SSa on the lower side. Thereby, a part of the terrace surface Tra near the step surface SSa is covered with the tapered portion TPa. When the tapered portion TPa is processed, processing is performed such that the width Wb in the X direction of the lower surface of the tapered portion TPa is greater than the layer thickness To of the insulating layer OL.

After the staircase portion SPa is formed, the mask pattern 72 is removed by ashing using oxygen plasma or the like.

As illustrated in insulating layer NLa covering the entirety of the staircase portion SPa is formed along the shape of the staircase portion SPa. As a result, a terrace surface TRb is formed on the terrace surface TRa.

The insulating layer NLa and the insulating layer NL have the main component in common. Specifically, the insulating layer NLa is, for example, a silicon nitride layer. The insulating layer NLa is an example of a third insulating layer.

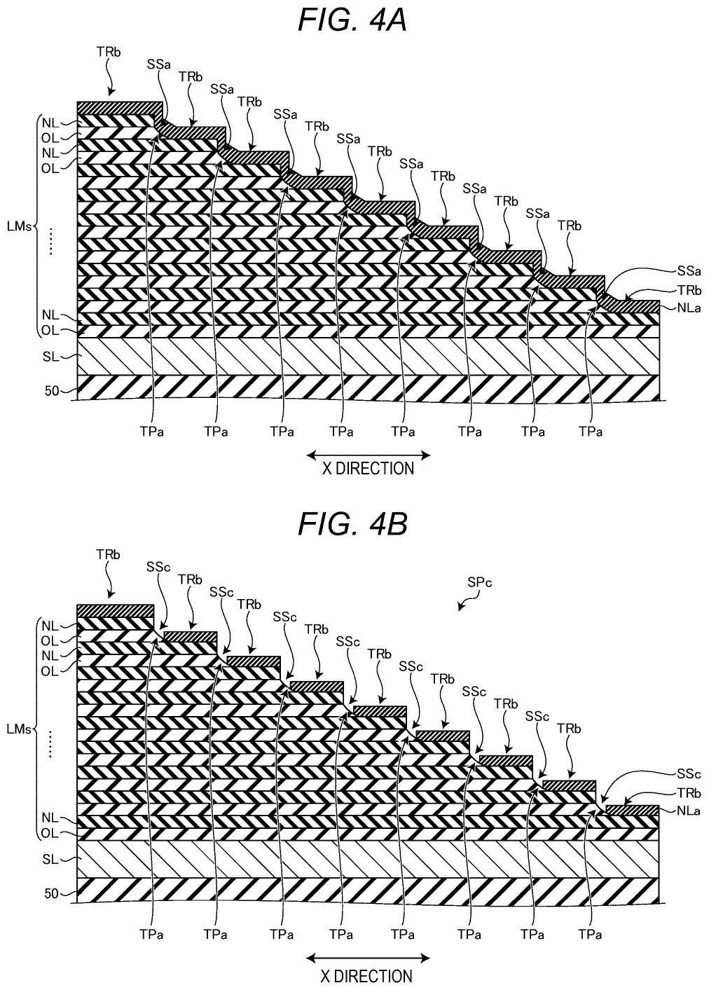

As illustrated in FIG. 4B, the insulating layer NLa covering the staircase portion SPa is etch-backed. At this time, anisotropic etching such as reactive ion etching (RIE) is used, for example. This enables removing the insulating layer NLa covering the step surface SSa with the insulating layer NLa forming the terrace surface TRb left.

Further, at this time, the tapered portion TPa formed at the lower side of the step surface SSa functions as an etching stopper layer when the insulating layer NLa covering the step surface SSa is removed. That is, downward etching for removing the insulating layer NLa is finished when the tapered portion TPa is reached. This is because the tapered portion TPa that is a silicon oxide layer or the like has a constant etching selectivity with respect to the insulating layer NLa that is a silicon nitride layer or the like. As described above, the tapered portion TPa serves as an etching stopper layer. This prevents the terrace surface TRa connected to the lower side of the step surface SSa from being etched unintentionally.

As a result, a staircase portion SPc that is to become the staircase portion SP later is formed.

The staircase portion SPc includes the plurality of terrace surfaces TRb and a plurality of step surfaces SSc. The plurality of step surfaces SSc is an end face in the X direction of the insulating layer OL, the insulating layer NL, and the insulating layer NLa.

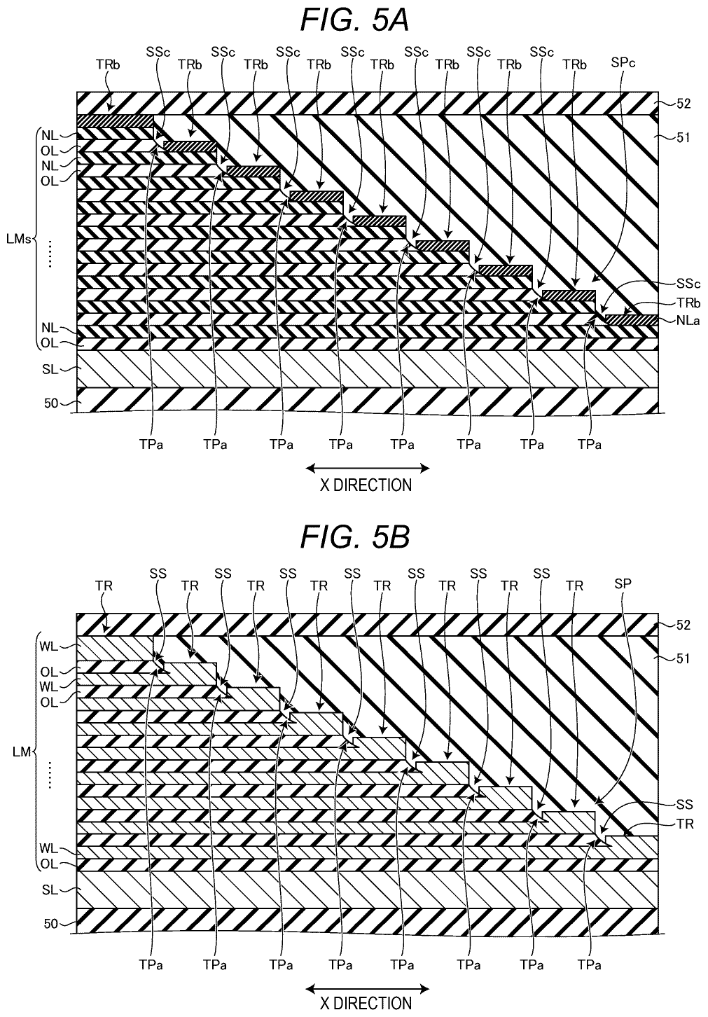

As illustrated in FIG. 5A, the insulating layer 51 is stacked to cover the staircase portion SPc and reach the height position of the upper surface of the unprocessed stacked body LMs. Further, the insulating layer 52 is formed to cover the upper surface of the unprocessed stacked body LMs and the insulating layer 51.

Although not illustrated in the drawing, the pillar PL is formed in the stacked body LMs using a predetermined method. It is noted that the pillar PL may be formed before the staircase region SR is formed.

The insulating layer NL and the insulating layer NLa of the stacked body LMs are removed using an etching solution, and metal such as tungsten is filled at the part removed. As a result, the word lines WL illustrated in FIG. 5B are acquired. Such processing of replacing the insulating layers with the word lines WL is sometimes referred to as replacement processing.

As a result of the processing described above, the stacked body LM is formed in which the plurality of word lines WL or the like and the plurality of insulating layers OL are alternately stacked one by one. In the stacked body LM, the staircase portion SP having the terrace surfaces TR and the step surfaces SS is formed.

In the staircase portion SP, the layer thickness of a part forming the terrace surface TR of the word line WL is formed to be greater than the layer thickness of the rest part of the corresponding word line WL. This is because after the insulating layer NLa is further stacked on the terrace surface TRa of the insulating layer NL, the insulating layer NL and the insulating layer NLa are replaced with the word lines WL.

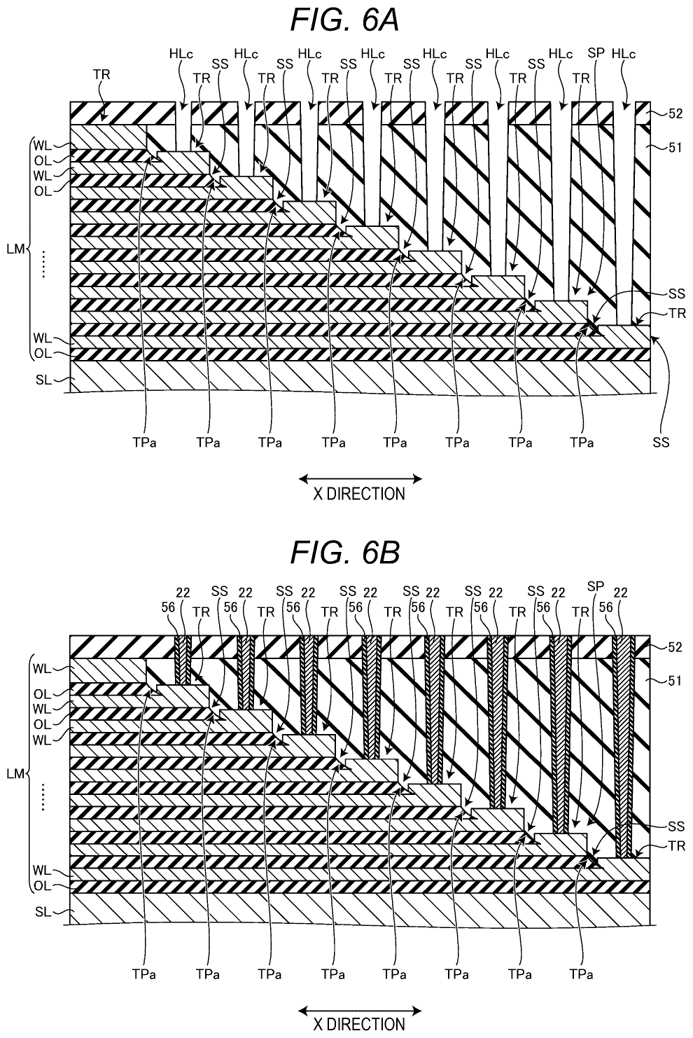

Next, FIGS. 6A and 6B illustrate how the contact CC is formed. As with FIGS. 3A to 5B, FIGS. 6A and 6B each illustrate a cross-section along the X direction of a region including the staircase portion SP.

As illustrated in FIG. 6A, a plurality of contact holes HLc is formed which penetrates the insulating layers 52 and 51 to reach the individual terrace surfaces TR. The contact hole HLc is a structure that results in the contact CC to be connected to the word line WL later.

The contact holes HLc have different depths of reach. As the contact hole HLc reaches the word line WL on the upper layer in the stacked body LM, the word line WL is excessively over-etched. However, since a part at which the terrace surface TR of the word line WL is to be formed is formed to have a thick layer, it is possible to prevent the lower ends of the plurality of contact holes HLc from penetrating the terrace surface TR even in a case where processing is applied under etching conditions in which the contact hole HLc having the greatest depth of reach can be processed.

As illustrated in FIG. 6B, the insulating layers 56 covering side walls of the contact holes HLc are formed.

Further, the conductive layers 22 such as tungsten layers are filled in voids of the contact holes HLc which remain inside the insulating layers 56. In the manner described above, the contact CC is formed.

Although not illustrated in the drawing, after the contact CC is formed, the insulating layers 53 and 54 are formed on the insulating layer 52, and the plug VO that is connected to the conductive layer 22 of the contact CC and extends in the insulating layer 53 and the upper layer wiring MX disposed in the insulating layer 54 are formed.

Further, although not illustrated in the drawing, after the formation of the contact CC, or, before the formation of the contact CC, the through contact C4 is formed in the through contact region TP. Further, the plate-shaped contact LI is formed at the timing before or on the formation of the through contact C4. Then, the upper layer wiring MX is connected to the through contact C4, the plate-shaped contact LI, and the contact CC, and a bit line (not illustrated) and the like is connected to the pillar PL.

In the manner described above, the semiconductor memory device 1 according to the first embodiment is manufactured.

### Comparative Example

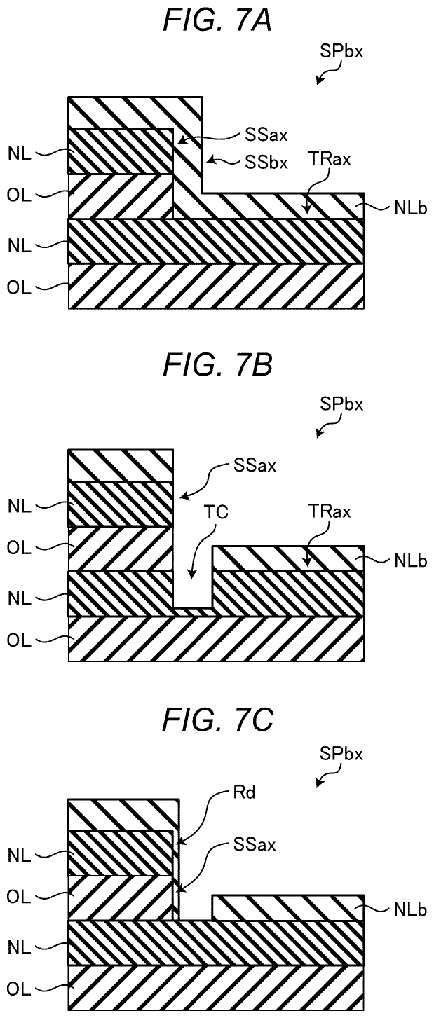

Next, a method for manufacturing a semiconductor memory device according to the comparative example will be described with reference to FIGS. 7A to 7C. FIGS. 7A to 7C are diagrams illustrating some procedures of the method for manufacturing the semiconductor memory device according to the comparative example.

FIG. 7A is a cross-sectional view illustrating a staircase portion SPbx in which an insulating layer NLb is formed in the method for manufacturing the semiconductor memory device according to the comparative example. FIG. 7B is a cross-sectional view illustrating an example of a state in which the insulating layer NLb in the step surface SSbx is removed. FIG. 7C is a cross-sectional view illustrating another example of the state in which the insulating layer NLb in the step surface SSbx is removed. In short, FIG. 7A corresponds to FIG. 4A of the first embodiment, and FIGS. 7B and 7C correspond to FIG. 4B of the first embodiment.

As illustrated in FIG. 7A, in the method for manufacturing the semiconductor memory device according to the comparative example, no tapered portion is formed in the staircase portion SPbx. After the insulating layer NLb is formed in the staircase portion SPbx, the insulating layer NLb mainly in the step surface SSbx is removed by processing such as RIE.

This sometimes forms a recess TC on a part of a terrace surface TRax as illustrated in FIG. 7B. The insulating layer NLb to be removed and the insulating layer NL forming the terrace surface TRax are both silicon nitride layers and so on. Therefore, even after the insulating layer NLb is removed, downward etching is not finished and etching progresses to the terrace surface TRax.

The formation of such a recess TC on the terrace surface TRax sometimes induces improper formation of the word line WL when the replacement processing is performed later. This inhibits the application of voltage to the memory cells via the word line WL for example, which possibly deteriorates the electrical characteristics of the semiconductor memory device.

On the other hand, in order to avoid the formation of the recess TC, it is possible to shorten the time of processing such as RIE, for example. In such a case, a residue Rd of the insulating layer NLb is possibly generated on a step surface SSax as illustrated in FIG. 7C.

If such a residue Rd is present on the step surface SSax, a portion of the residue Rs is replaced with a tungsten layer or the like when the replacement processing is performed later. Such a tungsten layer or the like extending over the word lines of the plurality of layers works as a leakage path, which sometimes causes a short in the plurality of word lines.

### Overview

According to the semiconductor memory device 1 of the first embodiment, in the staircase portion SP provided in a part of the stacked body LM in which the plurality of word lines WL and the plurality of insulating layers OL are alternately stacked one by one, the layer thickness of a part forming each of the terrace surfaces TR of the plurality of word lines WL is formed to be greater than the layer thickness of the rest part of the corresponding word lines WL.

This prevents the contact CC from penetrating the terrace surface TR at the time of formation of the contact CC, so that deterioration in electrical characteristics of the semiconductor memory device 1 can be prevented.

Further, the insulating layer OL that is the lowermost layer of the plurality of step surfaces SSa of the staircase portion SP has the tapered portion TPa extending toward the terrace surface TRa connected to the corresponding step surface SSa on the lower side.

Thereby, the tapered portion TPa protects the terrace surface TRa. Accordingly, in a case where the insulating layer NLa covering the step surface SSa is removed by etching, it is possible to prevent the recess TC from being formed on the terrace surface TRa. As a result, improper formation of the word line WL can be prevented when the replacement processing is performed later, so that deterioration in electrical characteristics of the semiconductor memory device 1 can be prevented.

Each of the plurality of terrace surfaces TR includes a first portion Pa where the layer thickness of the word line WL is formed to be thick and a second portion Pb where the layer thickness of the word line WL is smaller than that of the word line WL in the first portion Pa in the vicinity of a boundary with the corresponding step surface SS, and the first portion Pa covers an end, of the tapered portion TPa, on the terrace surface TR side.

This allows the entirety of the second portion Pb to be covered with the tapered portion TPa, which can avoid more reliably the formation of the recess TC on the terrace surface TRa. As a result, it is possible to prevent more reliably deterioration in electrical characteristics of the semiconductor memory device 1.

Further, the width Wb in the X direction of the lower surface of the tapered portion TPa is greater than the layer thickness To of the insulating layer OL.

Thereby, a distance between the first portions Pa of the plurality of terrace surfaces TR can be set to a distance or longer at which the step surface SS of the word line WL on the upper layer and the portion having a thicker film of the word line WL on the lower layer do not electrically affect each other. As a result, it is possible to prevent deterioration in electrical characteristics of the semiconductor memory device 1.

### Second Embodiment

### Configuration Example of Semiconductor Memory Device

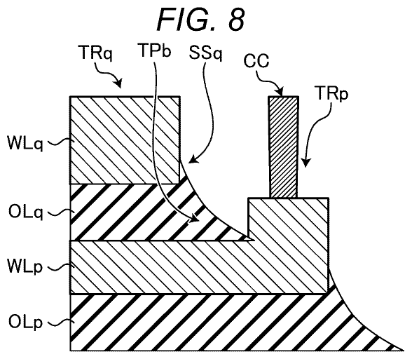

A semiconductor memory device 2 according to the second embodiment will be described with reference to FIG. 8. The semiconductor memory device 2 according to the second embodiment is different from the semiconductor memory device 1 of the first embodiment in shape of the tapered portion of the insulating layer OL. In the following description, the same elements as those of the first embodiment are denoted by the same reference numerals, and a description thereof is sometimes omitted.

FIG. 8 is a diagram illustrating an example of a detailed configuration of the semiconductor memory device 2 according to the second embodiment. FIG. 8 is a diagram corresponding to FIG. 2b of the first embodiment.

A stacked body of the second embodiment illustrated in FIG. 8 has a state in which, for example, an insulating layer OLp, a word line WLp, an insulating layer OLq, and a word line WLq are stacked from a lower place in the stated order.

A terrace surface TRp is formed on the word line WLp, and a terrace surface TRq is formed on the word line WLq. Further, a step surface SSq is connected to the terrace surface TRq thereabove, and is connected to the terrace surface TRp therebelow.

The insulating layer OLq, which is the lower layer, forming the step surface SSq has a tapered portion TPb extending toward the terrace surface TRp. The tapered portion TPb extends to a position corresponding to the word line WLq on the upper layer of the step surface SSq.

### Method for Manufacturing Semiconductor Memory Device

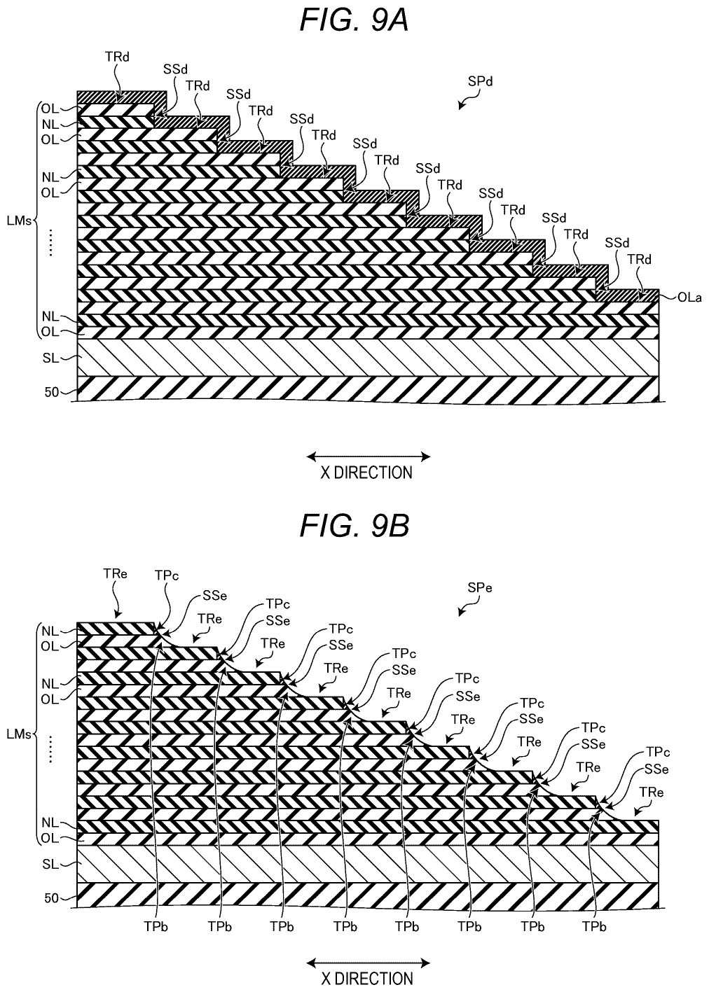

Next, a method for manufacturing the semiconductor memory device 2 according to the second embodiment will be described with reference to FIGS. 9A and 9B. FIGS. 9A and 9B are diagrams sequentially illustrating some procedures of the method for manufacturing the semiconductor memory device 2 according to the second embodiment. In the following description, the same elements as those of the foregoing embodiment are denoted by same reference numerals, and a description thereof is the sometimes omitted.

It is assumed that, prior to the processing illustrated in FIGS. 9A and 9B, the peripheral circuit CUA is already formed on the substrate SB and the insulating layer 50 covering the peripheral circuit CUA is already formed.

Prior to the processing illustrated in FIG. 9A, a staircase portion SPd is formed similarly to the first embodiment. The staircase portion SPd has a staircase shape in which the plurality of insulating layers NL and the plurality of insulating layers OL extend in the X direction. Each step of the staircase portion SPd includes one set of the insulating layer NL and the insulating layer OL.

The staircase portion SPd includes a plurality of terrace surfaces TRd formed with the plurality of insulating layers OL and a plurality of step surfaces SSd. The plurality of step surfaces SSd connects the plurality of terrace surfaces TRd in the stacking direction of a stacked body LMt. The staircase portion SPd is an example of a second staircase portion.

The terrace surface TRd is the upper surface of the insulating layer OL in each step of the staircase portion SPd. Further, the step surface SSd is the end face in the X direction of the insulating layer NL and the insulating layer OL in each step of the staircase portion SPd. The step surface SSd on the upper layer side is the insulating layer OL and the step surface SSd on the lower layer side is the insulating layer NL. The terrace surface TRd is an example of a second terrace surface. The step surface SSd is an example of a second step surface.

As illustrated in FIG. 9A, an insulating layer OLa, as a fourth insulating layer, covering the entirety of the staircase portion SPd is formed along the shape of the staircase portion SPd. The insulating layer OLa and the insulating layer OL have the main component in common. Specifically, the insulating layer OLa is, for example, a silicon oxide layer. The insulating layer OLa is an example of a fourth insulating layer.

As illustrated in FIG. 9A, etching is performed on a part of the insulating layer OLa, more specifically, on a part formed on the plurality of terrace surfaces TRd, and also is performed on a part of the plurality of insulating layers OL, more specifically, on a part forming the plurality of terrace surfaces TRd. This exposes a plurality of terrace surfaces TRe formed with the plurality of insulating layers NL. In this way, a staircase portion SPe as the first staircase portion is formed.

The staircase portion SPe includes the plurality of terrace surfaces TRe formed with the plurality of insulating layers NL and a plurality of step surfaces SSe. The plurality of terrace surfaces TRe corresponds to the plurality of terrace surfaces TRa of the first embodiment.

The terrace surface TRe is the upper surface of the insulating layer NL in each step of the staircase portion SPe. Further, the step surface SSe is the end face in the X direction of the insulating layer NL and the insulating layer OL in each step of the staircase portion Spe. The step surface SSe on the upper layer side is the insulating layer NL and the step surface SSe on the lower layer side is the insulating layer OL. The step surface SSe is connected to the terrace surface TRe on the upper side of the insulating layer NL and to the terrace surface TRe on the lower side of the insulating layer OL. The terrace surface TRe is an example of the first terrace surface. The step surface SSe is an example of the first step surface.

When the staircase portion SPe is formed, processing is performed such that the insulating layer OL that is the lower layer has a tapered portion TPb extending toward the terrace surface TRe connected to the step surface SSe on the lower side. Thereby, a part of the terrace surface TRe near the step surface SSe is covered with the tapered portion TPb.

When the tapered portion TPb is processed, processing is performed such that the insulating layer OLa covering the step surface SSd has a sloped surface continuous with the tapered portion TPb and also has a tapered portion TPc extending toward the terrace surface TRe from a position corresponding to the insulating layer NL that is the upper layer of the step surface SSe. The tapered portion TPc is configured with the insulating layer OLa, and thus the main component thereof is the same as that of the insulating layer OL.

As described above, the tapered portion TPc of which the main component is the same as that of the insulating layer OL is stacked on the tapered portion TPb configured with the insulating layer OL, so that the overall height of the tapered portion increases. This improves the function of the tapered portion as an etching stopper layer for a case where the insulating layer NLa is removed later. Increasing the overall height of the tapered portion makes it possible to reduce the gradient of the tapered shape. This enables the terrace surface TRe to cover a broader region.

Although not illustrated in the drawing, the insulating layer NLa is further stacked on the terrace surface TRe of the staircase portion SPe formed as described above. Thereafter, as with the first embodiment, the insulating layers 51 and 52 are formed, the replacement processing is performed, and the insulating layer is replaced with the word line WL. Then, the contact CC, the plug VO, the upper layer wiring MX, the through contact C4, and so on are formed, so that the semiconductor memory device according to the second embodiment is manufactured.

In the method for manufacturing the semiconductor memory device according to the second embodiment, the upper part of the tapered portion TPb extends to a position corresponding to the word line WL on the upper layer. However, the present disclosure is not limited thereto. The tapered portion TPb does not necessarily extend to a position corresponding to the word line WL on the upper layer, provided that the tapered portion TPb can function as an etching stopper layer for the terrace surface TRe.

While certain embodiments have been described, these embodiments have been presented by way of example only, and are not intended to limit the scope of the disclosure. These novel embodiments can be implemented in various other forms, and various omissions, substitutions, and changes can be made without departing from the spirit of the invention. The accompanying claims and their equivalents are intended to cover such forms or modifications as would fall within the scope and spirit of the disclosure.

What is claimed is:

1. A semiconductor memory device comprising:
a stacked body including a plurality of first conductive layers and a plurality of first insulating layers alternately stacked on top of one another, wherein
the stacked body further includes a staircase portion, the staircase portion having a plurality of terrace surfaces respectively formed with the plurality of first conductive layers and a plurality of step surfaces connecting the plurality of terrace surfaces in a stacking direction of the stacked body, the staircase portion extending in a first direction intersecting the stacking direction, wherein
each of the plurality of first conductive layers includes a first layer thickness and a second layer thickness, the first layer thickness corresponding to a portion of the first conductive layer forming the corresponding terrace surface and the second layer thickness corresponding to another portion of the first conductive layer, the first layer thickness is greater than the second layer thickness,
each of the plurality of first insulating layers has a tapered portion extending toward a corresponding one of the terrace surfaces, and
a width in the first direction of a lower surface of the tapered portion is greater than a layer thickness of each of the first insulating layers.

2. The semiconductor memory device according to claim 1,
wherein the second portion is disposed in a vicinity of a boundary with a corresponding one of the step surfaces, and
the first portion covers an end of the tapered portion, the end extending toward the terrace surface.

3. A method for manufacturing a semiconductor memory device comprising:
forming a stacked body including a plurality of first insulating layers and a plurality of second insulating layers alternately stacked on top of one another;
forming, in the stacked body, a first staircase portion having a plurality of first terrace surfaces formed with the plurality of first insulating layers and a plurality of first step surfaces connecting the plurality of first terrace surfaces in a stacking direction of the stacked body, the first staircase portion extending in a first direction intersecting the stacking direction, wherein each of the second insulating layers has a tapered portion extending toward a corresponding one of the terrace surfaces on a lower side, and a width in the first direction of a lower surface of the tapered portion is greater than a layer thickness of each of the first insulating layers;
covering the first staircase portion with a third insulating layer, wherein the first insulating layer and the third insulating layer have a similar component; and
removing a plurality of portions of the third insulating layers that cover the plurality of first step surfaces, respectively.

4. The method for manufacturing a semiconductor memory device according to claim 3, further comprising:
forming, in the stacked body, a second staircase portion having a plurality of second terrace surfaces formed with the plurality of second insulating layers and a plurality of second step surfaces connecting the plurality of second terrace surfaces in the stacking direction of the stacked body, the second staircase portion extending in the first direction,
covering the second portion with a fourth insulating layer, wherein the second insulating layer and the fourth insulating layer have a similar component, and
etching a portion of the fourth insulating layer formed on the plurality of second terrace surfaces and a portion of the plurality of second insulating layers forming the plurality of second terrace surfaces to expose the plurality of first terrace surfaces, and performing processing to form the tapered portion, among the plurality of second insulating layers, including a second insulating layer that is a lowermost layer of each of the plurality of first step surfaces and the fourth insulating layer.

5. The semiconductor memory device according to claim 1, further comprising a contact connected to the first portion of each of the terrace surfaces.

6. The semiconductor memory device according to claim 1, wherein the tapered portion of each of the plurality of first insulating layers extends into the first portion of a corresponding one of the terrace surfaces.

7. The semiconductor memory device according to claim 6, wherein the tapered portion of each of the plurality of first insulating layers is disposed directly above the second portion of a corresponding one of the terrace surfaces.

8. The semiconductor memory device according to claim 1, wherein, in the stacking direction, a lower one of the terrace surfaces is shifted away from an upper one of the terrace surfaces.

9. A method for manufacturing a semiconductor memory device comprising:
forming a stacked body including a plurality of first insulating layers and a plurality of second insulating layers alternately stacked on top of one another;
forming, in the stacked body, a staircase portion having a plurality of terrace surfaces formed with the plurality of first insulating layers and a plurality of step surfaces connecting the plurality of first terrace surfaces in a stacking direction of the stacked body, wherein each of the second insulating layers has a tapered portion extending toward a corresponding one of the terrace surfaces on a lower side;
covering the first staircase portion with a third insulating layer, wherein the first insulating layer and the third insulating layer have a similar component;
removing a plurality of portions of the third insulating layers that cover the plurality of step surfaces, respectively;
covering the staircase portion with an insulating layer; and
replacing the plurality of first insulating layers and remaining portions of the third insulating layers with a plurality of conductive lines, respectively.

10. The method for manufacturing a semiconductor memory device according to claim 9, wherein each of the plurality of conductive lines includes a first layer thickness and a second layer thickness, the first layer thickness corresponding to a first portion forming the corresponding terrace surface and the second layer thickness corresponding to a second portion disposed next to the first portion, and wherein the first layer thickness is greater than the second layer thickness.
